(19) United States
(12) Patent Application Publication
(10) Pub. No.: US 2007/0052089 A1
(43) Pub. Date: Mar. 8, 2007

(54) Adhesive film having multiple filler distribution and method of manufacturing the same, and chip stack package having the adhesive film and method of manufacturing the same

(75) Inventors: Won-Keun Kim, Cheonan-si (KR); Tae-Sung Park, Cheonan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/366,456

(22) Filed: Mar. 3, 2006

(30) Foreign Application Priority Data
Aug. 11, 2005 (KR) 2005-73968

(51) Int. Cl. H01L 23/34

(52) U.S. Cl. 257/723

(57) ABSTRACT

Disclosed herein are an adhesive film having a multiple filler distribution and a method of manufacturing the same, and a chip stack package having the adhesive film and a method of manufacturing the same. The adhesive film may have an upper film layer with a high concentration of fillers with a small particle size, and a lower film layer with a low concentration of fillers of a large particle size. The adhesive film having a multiple filler distribution may be manufactured using a lamination method or a consecutive coating method. The adhesive film may include two film layers having identical chemical properties while having different physical properties.

### PRIORITY STATEMENT

A claim of priority is made under 35 U.S.C. §119 to Korean Patent Application No. 2005-73968, filed on Aug. 11, 2005, the entire contents of which are incorporated herein by reference.

### BACKGROUND OF THE INVENTION

1. Field of the Invention

Example embodiments of the present invention generally relate to an adhesive film for a semiconductor chip and method of manufacturing the same. More particularly, example embodiments of the present invention relate to an adhesive film having a multiple filler distribution and a method of manufacturing same, a chip stack package including the adhesive film and a method of manufacturing the same.

2. Description of the Related Art

In recent years, along with an explosive growth in the field of electronic products, for example, portable information and communication devices, there has also been an increasing demand for memory devices capable of functioning as data storage media for these devices. Accordingly, there has been a demand for ever-increasing storage capacities of such memory devices. However, advances in memory chip development technology, for example, storage capacities for a single memory device, have not satisfied this market demand. Thus, stacking technologies, for example, stacking multiple chips or packages together to constitute the memory devices, have been actively pursued and researched as an alternative method of increasing storage capacity of memory devices.

In the stacking technology, in general, upper and lower chips may be attached together using an adhesive film to form a chip stack structure. In such a chip stack structure, the upper chip should not affect bonding wires connected to the lower chip, however, if a size of the upper chip is larger than or equal to the lower chip, fillers contained in the adhesive film may sometimes cause problems. Two such example problems are described below.

FIG. 1 is a sectional view illustrating a chip stack package having a conventional adhesive film.

Referring to FIG. 1, a chip stack package 10 may include a lower chip 13 attached to a package substrate 11 via an adhesive layer 12, and an upper chip 15 attached to the lower chip 13 via an adhesive film 14. The lower chip 13 may be electrically connected to the package substrate 11 via bonding wires 16. If the size of the upper chip 15 is larger than or equal to that of the lower chip 13, the adhesive film 14 may cover the bonding wires 16 of the lower chip 13.

A typical adhesive film 14 may be an adhesive resin base layer containing small filler particles. In a manufacturing process of the chip stack package 10, the adhesive film 14 may be attached to a lower surface of the upper chip 15 at a wafer level, and accordingly, the upper chip 15 having the adhesive film 14 attached thereto may be cut away from the wafer. The upper chip 15 having the adhesive film 14 may be attached to the lower chip 13 having the bonding wires 16 connected thereto. However, the wafer cutting and chip attachment processes may be dependent on an elastic modulus of the upper adhesive film 14.

A low elastic modulus of the adhesive film 14 may cause an unclean cut of the adhesive film 14 or edge breakage of the upper chip 15 during the wafer cutting process, and/or may cause the bonding wires 16 to penetrate into the adhesive film 14 and contact the upper chip 15 during the chip attachment process. However, if the elastic modulus of the adhesive film 14 is too high, the bonding wires 16 may not be able to penetrate into the adhesive film 14, and thus may be pressed against and/or may be deformed during the chip attachment process, and/or voids may develop within the adhesive film 14 and/or between the adhesive film 14 and the lower chip 13.

To solve the problems discussed above, it may be necessary to precisely control a height of loops of the bonding wires 16 and/or to precisely control temperature, pressure and other factors during the chip attachment process. These manufacturing processes constraints, however, may have an adverse impact upon the reliability and/or quality of the chip stack package 10.

FIG. 2 is a sectional view illustrating a chip stack package having another conventional adhesive film.

The chip stack package 20 of FIG. 2 may have an adhesive film 24, which is a composite film having two different material layers 24a and 24b. An upper material layer 24a may be made of, for example, a polyimide tape of a higher elastic modulus. A lower material layer 24b, which may have bonding wires 16 penetrated therein, may be made of, for example, a liquid epoxy of a lower elastic modulus. Such a composite dual adhesive film 24 may solve the above-described problems.

However, because the composite dual adhesive film 24 may be made of different types of materials having different properties, chemical/physical problems between the upper and lower material layers 24a and 24b may develop. For example, voids and/or a delamination phenomenon may develop at an interface between the two layers 24a and 24b. Other problems, for example, slow hardening and/or different hardening times for the different types of materials may also occur. As a result, these problems may adversely affect the reliability of the chip stack package 20.

### SUMMARY OF THE INVENTION

Accordingly, example embodiments of the present invention to provide an adhesive film which enhances reliability and/or producibility of a chip stack package utilizing the adhesive film.

Example embodiments of the present invention to provide an adhesive film which solves one or more problems in wafer cutting and chip attachment operations.

In an example embodiment of the present invention, an adhesive film having a multiple filler distribution including fillers distributed in a resin base layer, the adhesive film may include a first film layer having a first concentration of fillers, and a second film layer having a second concentration of fillers, and the second film layer being of a same material as the first film layer.

In another example embodiment of the present invention, a method of manufacturing an adhesive film may include forming a first film layer having a first filler having a first distribution therein on a first resin base layer, forming a second film layer having a second filler having a second distribution therein on a second resin base layer, and the second film layer being of a same material as the first film layer and the second film layer being of a same material as the first film layer. The method further including laminating the first film layer and second film layer to form the adhesive film.

In another example embodiment, a method of manufacturing an adhesive film may include coating a liquid first resin base layer mixed with the first filler on a cover film to form a second film layer, and coating a liquid second resin base layer mixed with the second filler on the first film layer to form a second film layer, and the second film layer being of a same material as the first film layer.

In another example embodiment of the present invention, a chip stack package may include an adhesive film having a multiple filler distribution including fillers distributed in a resin base layer, the adhesive film including, a first film layer having a high concentration of the fillers, and the second film layer being of a same material as the first film layer. The chip stack package may further include a lower integrated circuit chip under the second film layer, an upper integrated circuit chip on the first film layer, and a bonding wire coupled to the lower integrated circuit chip.

In an example embodiment of the present invention, a method of manufacturing of a chip stack package may include manufacturing an adhesive film having a multiple filler distribution including fillers distributed in a resin base layer, the adhesive film including, a first film layer having a first concentration of fillers, and a second film layer having a second concentration of fillers, and the second film layer being of a same material as the first film layer. The method may further include attaching the adhesive film to an upper integrated circuit chip such that the first film layer of the adhesive film faces a lower surface of the upper integrated circuit chip, coupling a bonding wire to the lower integrated circuit chip, and attaching the upper integrated circuit chip via the adhesive film on the lower integrated circuit chip such that the bonding wire penetrates a second film layer of the adhesive film.

In an example embodiment of the present invention, a method of manufacturing of a chip stack package may include manufacturing an adhesive film having a multiple filler distribution including fillers distributed in a resin base layer, the adhesive film including, a first film layer having a first concentration of fillers, and a second film layer having a second concentration of fillers, and the second film layer being of a same material as the first film layer. The method further including attaching the adhesive film to an upper integrated circuit chip such that the first film layer of the adhesive film faces a lower surface of the upper integrated circuit chip, coupling a bonding wire to the lower integrated circuit chip, and attaching the upper integrated circuit chip via the adhesive film on the lower integrated circuit chip such that the bonding wire penetrates a second film layer of the adhesive film.

### BRIEF DESCRIPTION OF THE DRAWINGS

FIG. 1 is a sectional view illustrating a chip stack package having a conventional adhesive film.

FIG. 2 is a sectional view illustrating a chip stack package having another conventional adhesive film.

FIG. 3 is a sectional view illustrating an adhesive film having a multiple filler distribution according to an example embodiment of the present invention.

FIGS. 4A and 4B are schematic diagrams illustrating manufacturing methods of an adhesive film having a multiple filler distribution according to an example embodiment of the present invention.

FIGS. 5A to 5D are sectional views illustrating a chip stack package and a manufacturing method thereof having an adhesive film according to an embodiment of the present invention.

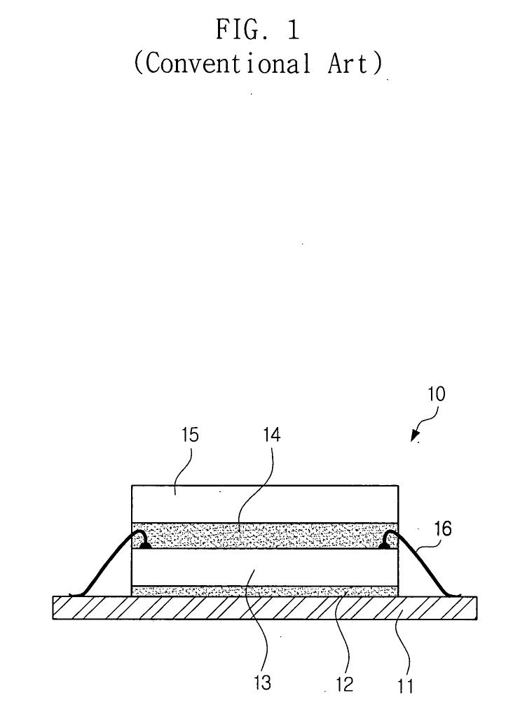

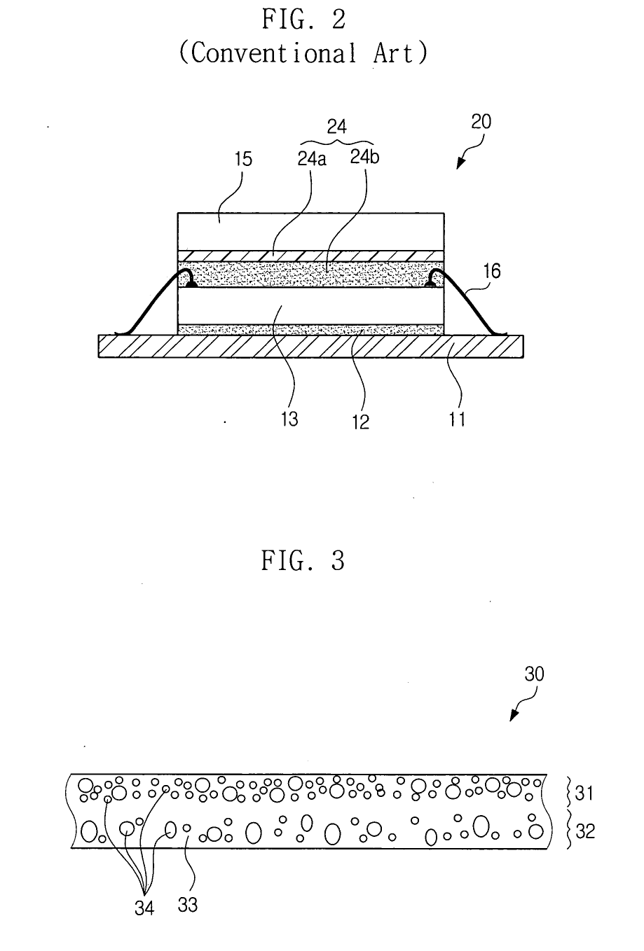

### DETAILED DESCRIPTION OF EXAMPLE EMBODIMENTS OF THE INVENTION

Hereinafter, example embodiments of the present invention will be described in detail with reference to the accompanying drawings.

Various embodiments are illustrated herein to assist those skilled in the relevant art in carrying out the example embodiments of the present invention without difficulty, but the illustrations are not to limit the scope of the example embodiments of the present invention. In the description, some constructions or processes may not be described or drawn for brevity. In the drawings, some elements may be exaggerated or only outlined, and thus may be not be drawn to scale. The same reference symbols may be given to the same or corresponding elements in the drawings.

FIG. 3 is a sectional view illustrating an adhesive film having a multiple filler distribution according to an example embodiment of the present invention.

As shown in FIG. 3, an adhesive film 30 may include fillers 34 distributed in a resin base layer 33. The resin base layer 33 may be a mixture of epoxy and acrylic resins, hardeners, and other materials. The fillers 34 may be inorganic or organic particles having a size of less than or equal to 20 μm.

The adhesive film 30 may include first and second film layers 31 and 32. The first film layer 31 may have a relatively higher concentration of the fillers 34 than the second film layer 32. For example, the concentration of the fillers 34 of the first film layer 31 may be in a range about 40 to 70 weight percent of the first film layer 31, and the concentration of the fillers 34 of the second film layer 32 may be in a range about 0 to 40 weight percent of the second film layer 32. A size of the particle of the filler 32 may also be different for the first and second film layers 31 and 32. For example, the size of a filler particle distributed in the first film layer 31 may be less than or equal to about 10 μm, and the size of a filler particle distributed in the second film layer 32 may be in a range about 10 to 20 μm.

As described above, compared to the second film layer 32, the first film layer 31 may have a higher concentration of the fillers 34 having a smaller particle size, and thus may have a higher elastic modulus or higher ability to deform. Conversely, the second film layer 32 may have a lower concentration of the fillers 34 of a larger particle size, and thus has a lower elastic modulus. Accordingly, the adhesive film 30 according to the example embodiments of the present invention may be characterized in a multiple filler distribution, for example, a dual filler distribution. That is, the adhesive film 30 may include two layers having identical chemical properties but having different physical properties.

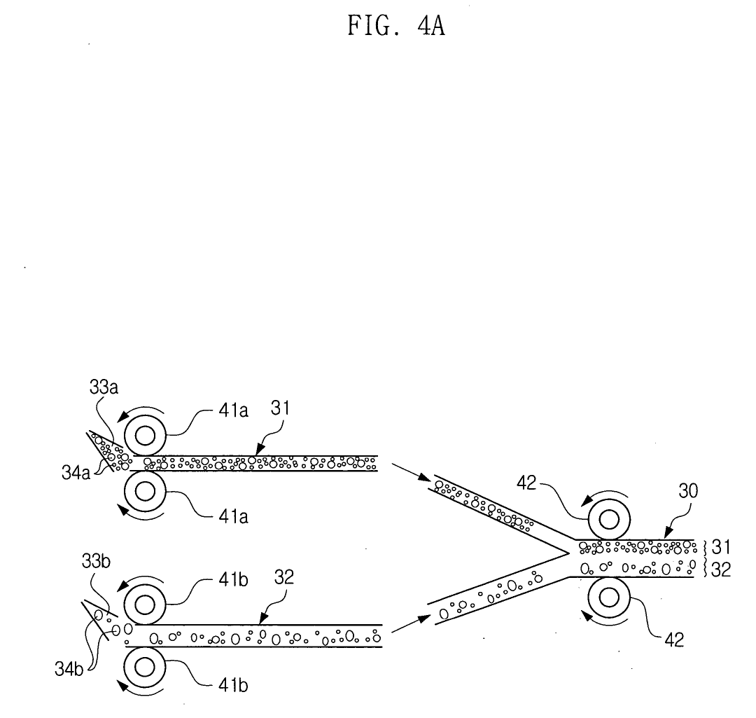

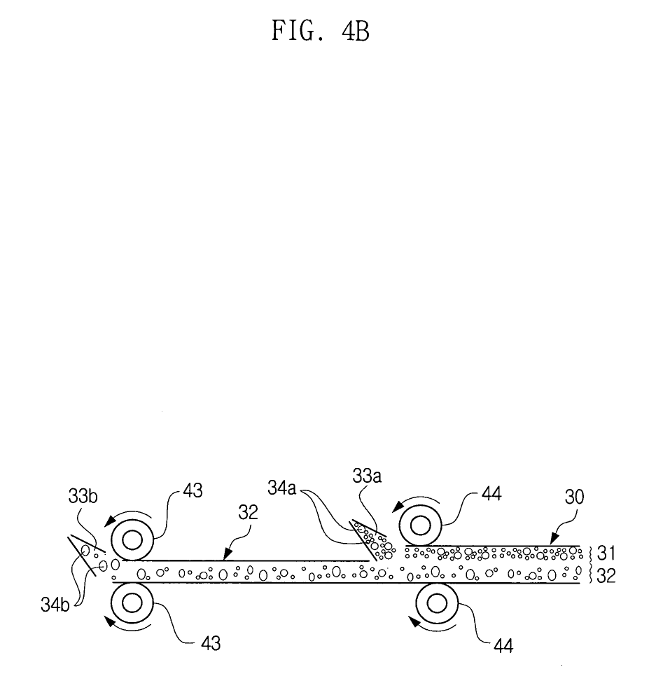

FIGS. 4A and 4B are schematic diagrams illustrating methods of manufacturing an adhesive film having a multiple filler distribution according to example embodiments of the present invention.

An adhesive film in accordance with example embodiments of the present invention may be manufactured using several methods. For example, a lamination method is illustrated in FIG. 4A, and a consecutive coating method is illustrated in FIG. 4B.

In the lamination method shown in FIG. 4A, a first film layer 31 and a second film layer 32 may be formed separately and then laminated together.

The first film layer 31 may include a first filler 34a that may be densely distributed in a first resin base layer 33a. A liquid first resin base layer 33a mixed with the first filler 34a may be coated on a first cover film (not shown), extruded through a first set of rollers 41a, dried, and partially hardened to form the first film layer 31.

The second film layer 32 may include a second filler 34b that may be sparsely distributed in a second resin base layer 33b. A liquid second resin base layer 33b mixed with the second filler 34b may be coated on a second cover film (not shown), extruded through a second set of rollers 41b, dried, and partially hardened to form the second film layer 32.

The separately formed first and second film layers 31 and 32 may be laminated together by compressing the two layers with a third set of rollers 42 into the adhesive film 30. The first and second cover films may be placed facing away from each other, and removed after the lamination process. The first and second cover films may be made of, for example, polyethylene resin. Base films that are widely utilized in a wafer cutting operation may be used instead of the cover films. The base films may be made of, for example, polyolefin resin.

In a consecutive coating method illustrated in FIG. 4B, a second film layer 32 may be formed, and a first film layer 31 may be coated on the second film layer 32.

A liquid second resin base layer 33b mixed with the second filler 34b may be coated on a cover film (not shown) and extruded through a fourth set of rollers 43 to form the second film layer 32. A liquid first resin base layer 33a mixed with first a filler 34a may be coated onto the second film layer 32 and extruded through a fifth set of rollers 44 to form the first film layer 31. The first and second film layers 31 and 32 may be dried, partially hardened, and the cover film may be removed to form the adhesive film 30. Alternatively, in the consecutive coating method, the first film layer 31 may be formed first, and the second film layer 32 may be coated onto the first film layer 31.

The above-described adhesive film having a multiple filler distribution may be utilized in a chip stack package.

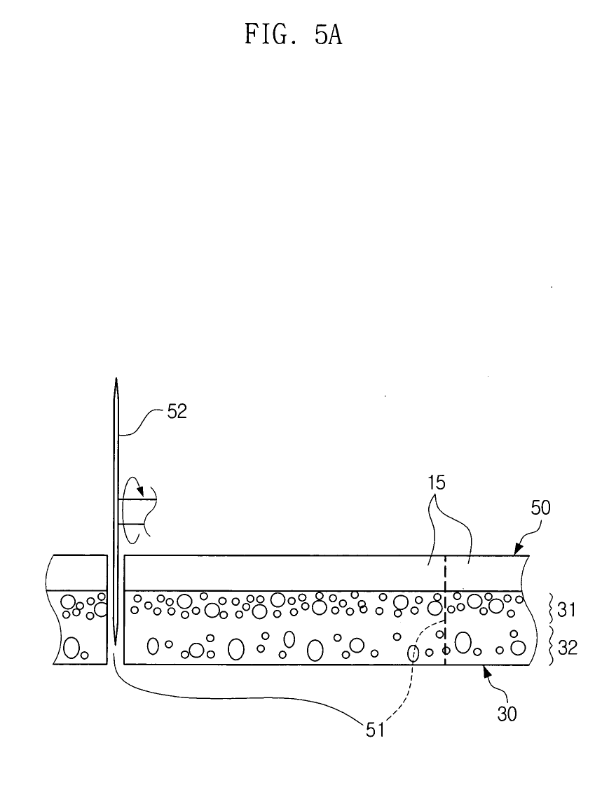

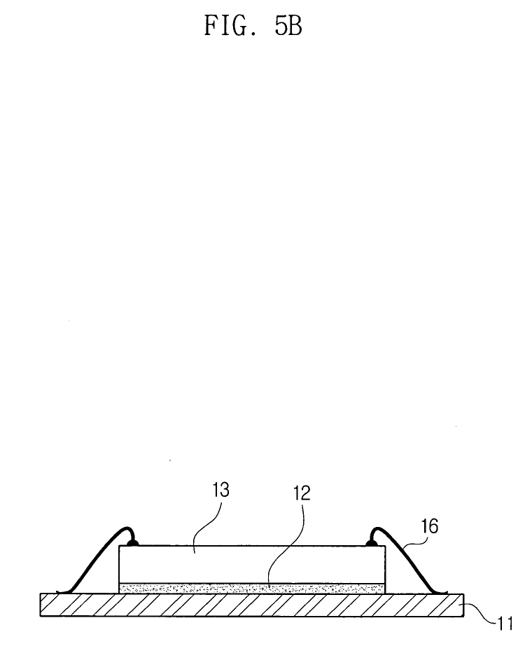

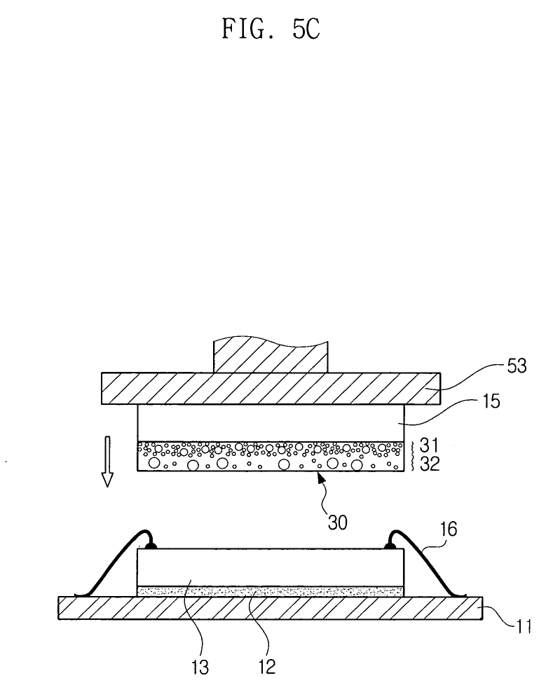

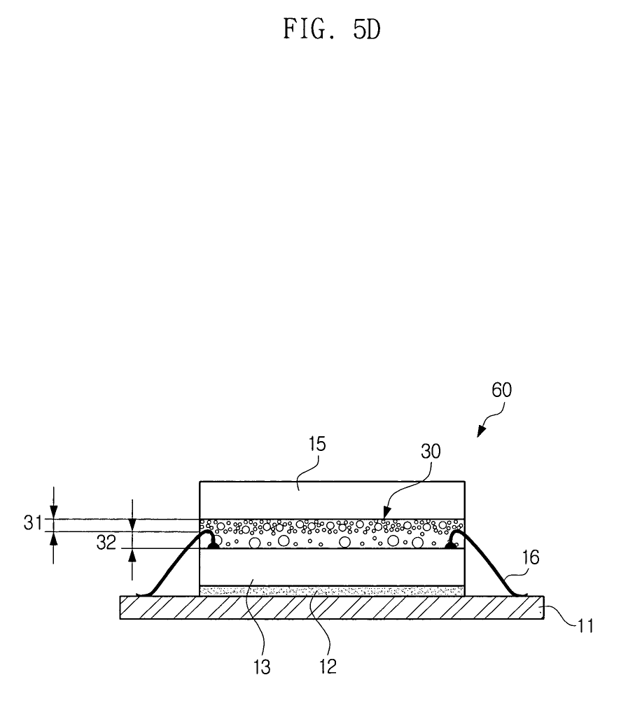

FIGS. 5A to 5D are sectional views illustrating a chip stack package and a manufacturing method thereof using an adhesive film according to an example embodiment of the present invention.

An adhesive film 30 having a multiple filler distribution may be manufactured as described above with respect to FIGS. 4A and 4B. The adhesive film 30 may be attached on an upper chip 15 as shown in FIG. 5A. A first film layer 31 of the adhesive film 30 may contact a lower surface of the upper chip 15. An adhesive film attachment process may be performed on a wafer 50, in other words, wafer level. The wafer 50 and adhesive film 30 may be cut into individual chips by a wafer cutting process, in which the wafer 50 may be cut along scribe areas 51 with a cutting tool, for example, a rotating blade 52 or a laser as is well known in the art.

As shown in FIG. 5B, a lower chip 13 may be attached on a package substrate 11 by an adhesive layer 12, and the lower chip 13 may be electrically connected to the package substrate 11 via bonding wires 16. As is well known in the art, the package substrate 11 may be, for example, a printed circuit board (PCB) or leadframe, the adhesive layer 12 may be made of silicone or epoxy-based adhesives, and the bonding wires 16 may be made of a metal, for example, gold or aluminum.

As shown in FIG. 5C, the upper chip 15 having the adhesive film 30 may be attached on the lower chip 13. The bonding wires 16 may penetrate into the second film layer 32 having a lower elastic modulus, but may not penetrate into the first film layer 31 having a higher elastic modulus. As is well known in the art, the chip attachment process may be performed using a chip attachment apparatus 53 with a desired amount of heat or pressure may be applied during the process.

FIG. 5D shows a chip stack package 60 of an example embodiment of the present invention manufactured according to the above described method. As shown in FIG. 5D, the chip stack package 60 may include the lower chip 13 under the second film layer 32 of the adhesive film 30, and the upper chip 15 on the first film layer 31 of the adhesive film 30. The bonding wires 16 coupled to the lower chip 13 may penetrate into the second film layer 32.

The structure of the chip stack package 60 having the adhesive film 30 may be useful when a size of the upper chip 15 is larger than or equal to that of the lower chip 13. Other constructions of the chip stack package 60, for example, electrical connection between the upper chip 15 and the package substrate 11, external interface terminals, and package protection members are well known in the art and will not be described herein.

Although the adhesive film described in example embodiments may include multiple film layers, for example two film layers, the adhesive film of the example embodiments of the present invention is not limited thereto, and may include more than two layers having different filler distributions from each other. In addition, although the chip stack package described in the example embodiments may include two stacked integrated circuit chips, the chip stack package of the example embodiments of the present invention may not be limited thereto, and may include more than two stacked integrated circuit chips.

As apparent from the above description, example embodiments of the present invention provide an adhesive film wherein a multiple distribution of fillers in the adhesive film may permit simultaneous solution of various problems due to an elastic modulus of the adhesive film. In other words, because an upper film layer of the adhesive film contacting with an upper chip has a higher concentration of fillers and a high elastic modulus, unclean cutting of the adhesive film or edge breakage of the upper chip may be reduced or prevented during a wafer cutting process. The upper film layer of the adhesive film having a higher elastic modulus may also reduce or prevent bonding wires from contacting with the upper chip in a chip attachment process. In addition, because a lower film layer of the adhesive film contacting with a lower chip has a lower concentration of fillers and a lower elastic modulus, the bonding wires may easily penetrate into the lower film layer and may not be deformed by the adhesive film during the chip attachment process, and development of voids within the adhesive film and/or between the adhesive film and the lower chip may be reduced or prevented.

Furthermore, the adhesive film having a multiple filler distribution in accordance example embodiments of the present invention may include at least two film layers having identical chemical properties while having different physical properties. Thus, the adhesive film reduce or may prevent development of voids and/or delamination phenomenon at an interface between upper and lower film layers, and/or other unexpected problems due to differences in the materials forming the upper and lower film layers.

Accordingly, the adhesive film provided by example embodiments of the present invention may enhance reliability and/or reproducibility of chip stack packages.

The present invention is disclosed in example embodiments shown in this specification and in the accompanying drawings using specific terms. This disclosure is not to limit the scope of the example embodiments of the present invention, but to serve only for illustrative purposes. It should be understood to the ordinary person skilled in the art that various changes or modifications of the example embodiments are possible without departing from the scope of the present invention.

What is claimed is:

1. An adhesive film having a multiple fillers distribution in a resin base layer, the adhesive film comprising:
a first film layer having a first concentration of filler; and
a second film layer having a second concentration of filler, and the second film layer being of a same material as the first film layer.

2. The adhesive film of claim 1, wherein the concentration of the filler of the first film layer is in a range about 40 to 70 weight percent of the first film layer.

3. The adhesive film of claim 1, wherein the concentration of the filler of the second film layer is in a range about 0 to 40 weight percent of the second film layer.

4. The adhesive film of claim 1, wherein the fillers have a particle size of less than or equal to about 20 μm.

5. The adhesive film of claim 1, wherein the filler distributed in the first film layer have a particle size of less than or equal to about 10 μm.

6. The adhesive film of claim 1, wherein the filler distributed in the second film layer have a particle size of about 10 to 20 μm.

7. The adhesive film of claim 1, wherein the resin base layer includes at least one of epoxy resin, acrylic resin, and hardeners.

8. The adhesive film of claim 1, wherein the first and second filler are made of inorganic or organic particles.

9. The adhesive film of claim 1, wherein the first film layer has a higher elastic modulus than the second film layer.

10. A method of manufacturing an adhesive film, comprising:
forming a first film layer having a first filler having a first distribution therein on a first resin base layer;
forming a second film layer having a second filler having a second distribution therein on a second resin base layer, and the second film layer being of a same material as the first film layer; and
laminating the first film layer and second film layer to form the adhesive film.

11. The method of claim 10, wherein forming the first and second film layers include:
coating a liquid first resin base layer mixed with the first filler on a first cover film, drying, and partially hardening the coated first resin base layer; and
coating a liquid second resin base layer mixed with the second filler on a second cover film, drying, and partially hardening the coated second resin base layer.

12. The method of claim 11, wherein laminating process includes compressing the first film layer and second film layer such that the first cover film and second cover film are placed facing away from each other.

13. The method of claim 12, further comprising removing the first cover film and second cover film after the compressing process.

14. The method of claim 11, wherein the first film layer has a higher elastic modulus than the second film layer

15. A method of manufacturing an adhesive film, comprising:
coating a liquid first resin base layer mixed with a first filler on a cover film to form a second film layer; and
coating a liquid second resin base layer mixed with a second filler on the first film layer to form a second film layer, and the second film layer being of a same material as the first film layer.

16. The method of claim 15, further including:
drying, partially hardening the first film layer; and
drying, partially hardening the second film layer.

17. The method of claim 16, further comprising removing the cover film.

18. The method of claim 15, wherein the first film layer has a higher elastic modulus than the second film layer.

19. A chip stack package, comprising:
an adhesive film having a multiple filler distribution including fillers distributed in a resin base layer, the adhesive film including,
a first film layer having a first concentration of fillers, and
a second film layer having a second concentration of fillers, and the second film layer being of a same material as the first film layer;
a lower integrated circuit chip under the second film layer;
an upper integrated circuit chip on the first film layer; and
a bonding wire coupled to the lower integrated circuit chip.

20. The chip stack package of claim 19, wherein a size of the upper integrated circuit chip is larger than or equal to the lower integrated circuit chip.

21. The chip stack package of claim 19, wherein the first film layer has a higher elastic modulus than the second film layer.

22. A method of manufacturing of a chip stack package, comprising:
manufacturing an adhesive film having a multiple filler distribution including fillers distributed in a resin base layer, the adhesive film including,
a first film layer having a first concentration of fillers, and
a second film layer having a second concentration of fillers, and the second film layer being of a same material as the first film layer;
attaching the adhesive film to an upper integrated circuit chip such that the first film layer of the adhesive film faces a lower surface of the upper integrated circuit chip;
coupling a bonding wire to the lower integrated circuit chip; and
attaching the upper integrated circuit chip via the adhesive film on the lower integrated circuit chip such that the bonding wire penetrates a second film layer of the adhesive film.

23. The method of claim 22, wherein the attaching the adhesive film to the upper integrated circuit chip is in a wafer level.

24. The method of claim 23, wherein further including separating the upper integrated circuit chip having a portion of the adhesive film attached thereto from the wafer by a wafer cutting process.

25. The method of claim 22, wherein the first film layer has a higher elastic modulus than the first film layer.
